(19) United States
(12) Patent Application Publication
(10) Pub. No.: US 2002/0158989 A1
(43) Pub. Date: Oct. 31, 2002

(54) Image encoding device, image encoding method to be used therein and storage medium storing program

(75) Inventor: Atsushi Ohkubo, Tokyo (JP)

Correspondence Address: FOLEY AND LARDNER, SUITE 500, 3000 K STREET NW, WASHINGTON, DC, 20007, US

(73) Assignee: NEC CORPORATION

(21) Appl. No.: 10/128,345

(22) Filed: Apr. 24, 2002

(30) Foreign Application Priority Data
Apr. 25, 2001 (JP) 2001-126843

(51) Int. Cl. H03M 1/12

(52) U.S. Cl. 348/572

(57) ABSTRACT

An image encoding device and an image encoding method to be used therein can reduce generated code amount for permitting assignment of large coding amount to a portion where the most significant variation is caused, and whereby improvement of image quality is realized. The device performs image encoding by determining a motion vector amount of an image. The device makes judgment whether a motion vector amount calculated by using a preliminarily set difference threshold value can be replaced with a motion vector amount one preceding macro block.

### BACKGROUND OF THE INVENTION

1. Field of the Invention

The present invention relates generally to an image encoding device and an image encoding method to be used therein and storage medium storing program. More particularly, the invention relates to an image encoding defined in H.261 or H.263 of ITU-T Recommendation.

2. Description of the Related Art

In the image encoding defined in H.261 or H.263 of ITU-T Recommendation, algorithm detecting motion between a preceding frame and a current frame and digitizing as a motion vector amount for reducing generated code amount, has been employed in order to realize image transmission at low bit rate. Such process is called as motion estimating process

The procedure of such process is illustrated in FIG. 6. In FIG. 6, the motion estimating portion 11 performs retrieval of the position of a macro block in the preceding frame within a range per macro block for determining motion vector when replacement by motion vector is possible.

When a value is determined as a motion vector amount, a variable length encoding processing portion 12 effects conversion into a variably encoded value from a difference value of the determined value and a value derived in the preceding macro block and thus determined a motion vector data of the macro block. If the determined motion vector amount is the same motion vector amount of the preceding macro block, the variably encoded value is determined as “1”.

In H.261 and H.263 of ITU-T Recommendation, assignment is made that the variable encoding value becomes smaller at smaller difference of the motion vector amount of adjacent macro block.

In the foregoing conventional image encoding, upon realizing real time image transmission, image encoding has to be realized within a given communication speed range. Therefore, a coding amount range in one frame is preliminarily determined and encoding is performed so that the coding amount falls within the predetermined coding amount range, the image transmission with lesser delay is realized in combination with the skip process.

In this case, the coding amount has to be made smaller at lower communication speed, the coding amount does not fall within the range assigned in a extra-low bit rate less than or equal to 64 kbps to frequently cause skip process or delay to cause significant degradation of the image quality.

### SUMMARY OF THE INVENTION

The present invention has been worked out in view of the problem set forth above. It is therefore an object of the present invention to provide an image encoding device and an image encoding method to be used therein and storage medium storing program, which can reduce generated code amount for permitting assignment of large coding amount to a portion where the most significant variation is caused, and whereby improvement of image quality is realized.

According to the first aspect of the present invention, an image encoding device for performing image encoding by determining a motion vector amount of an image comprises:

judgment processing means for processing judgment whether a motion vector amount calculated by using a preliminarily set difference threshold value can be replaced with a motion vector amount one preceding macro block.

According to the second aspect of the present invention, an image encoding method for performing encoding of an image for determining a motion vector amount of the image comprises a step of:

processing judgment whether a motion vector amount calculated by using a preliminarily set difference threshold value can be replaced with a motion vector amount one preceding macro block.

In the foregoing image encoding device, when the difference of motion vector amounts of adjacent macro blocks falls within a range of the difference threshold value upon determination of the motion vector amount, the motion vector amount of the macro block currently on process is made the same as the motion vector amount of one preceding macro block.

The motion vector data of the macro block currently on process may converted into “1” of bit amount 1 by making the motion vector amount of the macro block currently on process the same as the motion vector amount of one preceding macro block. Namely, when the difference of the motion vector amounts of adjacent macro blocks falls within the range of the difference threshold value, the motion vector data of the right-hand adjacent macro block on a screen is converted the motion vector data into “1”.

Thus, assignment of the coding amount for the portion where the most significant variation is caused, can be made large to realize improvement of the image quality with reducing the generated code amount. Namely, focusing to the motion vector of adjacent macro blocks it becomes possible to realize image quality improving method of the image encoding for reducing bit amount.

According to the third aspect of the present invention, a storage medium storing a program for making a computer to execute an image encoding process for encoding of an image for determining a motion vector amount of the image comprises a step of:

processing judgment whether a motion vector amount calculated by using a preliminarily set difference threshold value can be replaced with a motion vector amount one preceding macro block.

### BRIEF DESCRIPTION OF THE DRAWINGS

The present invention will be understood more fully from the detailed description given hereinafter and from the accompanying drawings of the preferred embodiment of the present invention, which, however, should not be taken to be limitative to the invention, but are for explanation and understanding only.

In the drawings:

FIG. 1 is a block diagram showing a construction of one embodiment of an image encoding device according to the present invention;

FIG. 2 is an illustration showing a relationship between an image frame and a macro block on one embodiment of the image encoding device according to the present invention;

FIG. 3 is a flowchart showing operation of a difference judgment processing portion of FIG. 1;

FIG. 4 is an illustration showing a relationship between an image frame and a macro block on another embodiment of the image encoding device according to the present invention;

FIG. 5 is an illustration showing a construction of a difference judgment processing portion in another embodiment of the present invention;

FIG. 6 is a block diagram showing a construction of the conventional image encoding device.

### DESCRIPTION OF THE PREFERRED EMBODIMENT

The present invention will be discussed hereinafter in detail in terms of the preferred embodiment of the present invention with reference to the accompanying drawings. In the following description, numerous specific details are set forth in order to provide a thorough understanding of the present invention. It will be obvious, however, to those skilled in the art that the present invention may be practiced without these specific details. In other instance, well-known structure is not shown in detail in order to avoid unnecessary obscurity of the present invention.

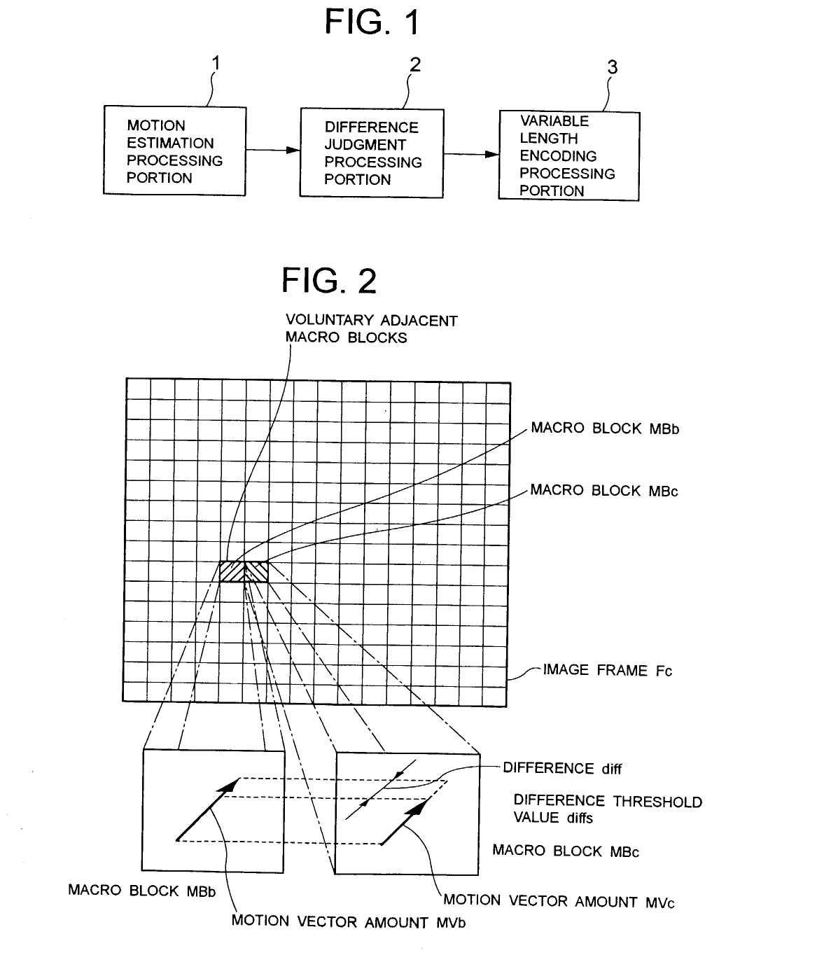

FIG. 1 is a block diagram showing a construction of one embodiment of an image encoding device according to the present invention. In FIG. 1, one embodiment of the image encoding device of the present invention is constructed with a motion estimation processing portion 1, a difference judgment processing portion 2 and a variable length encoding processing portion 3.

The motion estimation processing portion 1 performs calculation of motion vector amount of a macro block. The difference judgment processing portion 2 performs process for judgment whether the motion vector amount calculated in the motion estimation processing portion 1 can be replaced with the motion vector amount of one preceding macro block or not. The variable length encoding processing portion 3 converts the motion vector amount into a variable length encoded motion vector data.

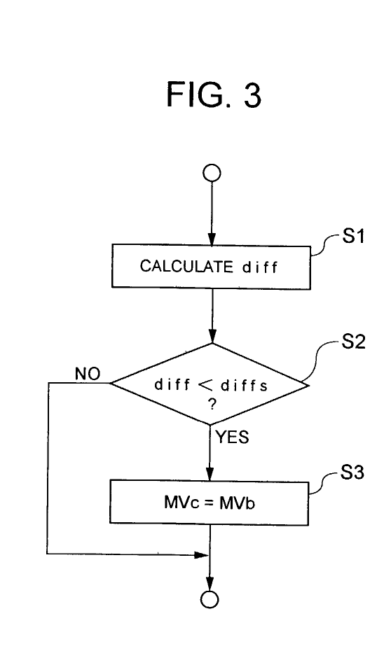

FIG. 2 is an illustration showing a relationship between an image frame and the macro block in one embodiment of the image encoding device according to the present invention, and FIG. 3 is a flowchart showing operation of the difference judgment processing portion 2 of FIG. 1. Operation of one embodiment of the image encoding device according to the present invention will be discussed with reference to FIGS. 1 to 3.

In determination of motion vector amount in image encoding, when a difference of respective motion vector amounts MVb and MVc of adjacent macro blocks MBb and MBc shown in FIG. 2 falls within a range of a preliminarily set difference threshold value diffs, the motion vector amount MVc of the macro block MBc currently on motion estimation process is set to the same as the motion vector amount MVb of one preceding macro block.

As set forth above, by setting the motion vector amount at the same value, a motion vector data MVDc is converted into “1” of bit amount 1. Namely, when a difference of respective motion vector amounts MVb and MVc of adjacent macro blocks MBb and MBc falls within a range of the difference threshold value diffs, the motion vector data of the right-hand adjacent macro block MBc on the screen is converted into “1”.

By this, it becomes possible to assign large coding amount for the portion causing the most significant variation with reducing the generated code amount to realize improvement of image quality.

For discussing more particularly, the current image frame is assumed as Fc. Among two adjacent macro blocks presenting in the image frame Fc, the macro block for which motion estimation is to be performed currently, is assumed as MBc, and the left-hand adjacent macro block is assumed as MBb. Also, the motion vector calculated with respect to the macro block MBb is assumed as MVb.

Assuming that the motion vector amount determined with respect to the macro block MBc is MVc, the difference diff of the motion vector amounts MVb and MVc of these macro blocks MBb and MBc is expressed by the following equation (step S1 of FIG. 3):

diff=|MVc−MVb |

The preliminarily set difference threshold value before execution of image encoding is assumed as diffs. At first, the motion vector amount MVc of the macro block MBc is calculated by the motion estimation processing portion 1.

Next, with the difference threshold value diffs, the motion vector amount MVc is judged whether it can be replaced with the motion vector amount MVb of one preceding macro block MBb (diff<diffs) in the difference judgment processing portion 2 (step S2 of FIG. 3). If judgment is made that it can be replaced with the motion vector amount MVb of one preceding macro block MBb, the motion vector amount MVc is replaced with the motion vector amount MVb of one preceding macro block MBb (step S3 of FIG. 3).

The motion vector amount MVc generated by the difference judgment processing portion 2 is converted into the variable length encoded motion vector data MVDc via the variable length encoding processing portion 3.

The difference judgment processing portion 2 makes judgment whether the difference of the motion vector amounts MVb and MVc of the adjacent macro blocks MBb and MBc falls within a range of the difference threshold value diffs or not. If the difference of the motion vector amounts MVb and MVc of the adjacent macro blocks MBb and MBc falls within a range of the difference threshold value diffs, the motion vector amount MVc of the macro block MBc is made the same as the motion vector amount MVb of one preceding macro block MBb. By making the motion vector amount at the same value, the motion vector data is converted into “1” of bit amount 1.

Namely, if the difference of the motion vector amounts MVb and MVc of the adjacent macro blocks MBb and MBc falls within a range of the difference threshold value diffs, the motion vector data of the macro block MBc on right-hand side of the screen is converted into “1”.

As set forth above, the motion vector data of respective of adjacent macro blocks MBb and MBc falling within the range of difference threshold value diffs can be represented by bit amount 1. Therefore, generated code amount can be reduced.

On the other hand, by reducing the generated code amount, it becomes possible to assign large coding amount to the portion where the most significant variation is caused. Therefore, improvement of image quality can be achieved even when scene variation is significant.

Furthermore, since only process for converting the motion vector amount into the given value, it can be decoded even by conventionally available decoder. Therefore it can be used in the conventional image encoding algorithm.

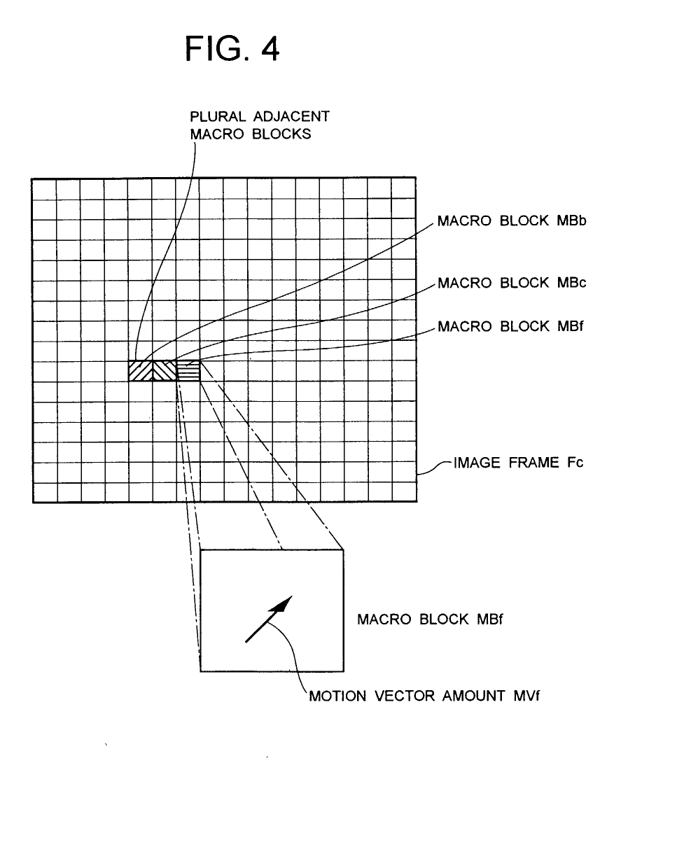

FIG. 4 is an illustration showing a relationship between the image frame and the macro block in another embodiment of the image coding device according to the present invention. As. shown in FIG. 4, in another of the present invention, if a difference of a motion vector amount MVf of the macro block MBf which is on right-hand side of the macro block MBb and MBc, for which replacement of the motion vector amount is applied, and a motion vector amount MVc falls within a range of difference threshold value diffs, the motion vector amount MVf is replaced with the motion vector amount MVc.

Namely, the motion vector amount MVf is replaced with the motion vector amount MVb. Therefore, if the difference of the motion vector amount of a plurality of adjacent macro blocks falls within the range of the difference threshold value diffs, the motion vector amount MVf of the macro block MBf to be processed finally is replaced with the motion vector amount MVb of the macro block MBb to be processed at first.

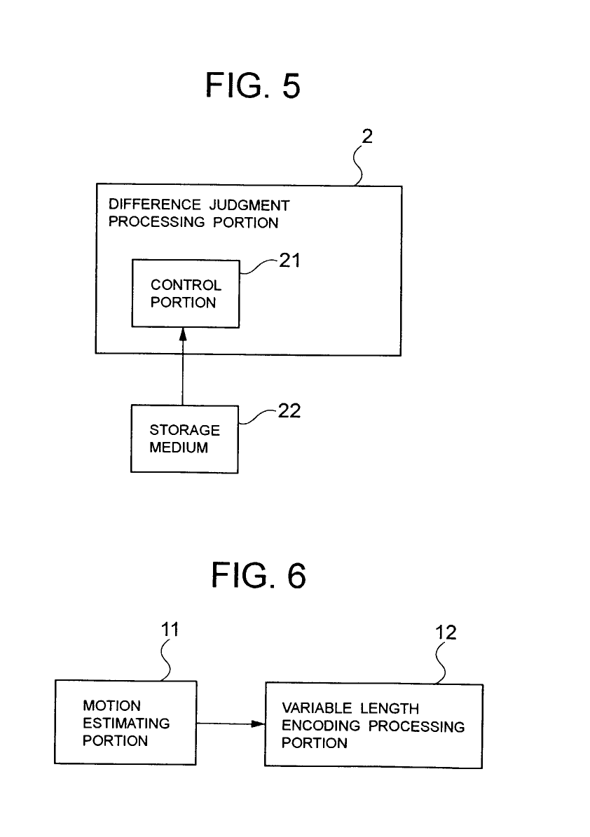

FIG. 5 is an illustration showing a construction of another embodiment of the image encoding device according to the present invention. FIG. 5 shows one example showing the construction of the difference judgment processing portion 2. With reference to FIG. 5, the difference judgment processing portion 2 includes a control portion 21. On the other hand, a storage medium 22 is provided outside of the difference judgment processing portion 2. In the storage medium 22, a program to make the control portion 21 to execute the process shown in the flowchart of FIG. 3, is stored.

The control portion 21 reads out the program from the storage medium 22 to write in a not shown storage portion. Then, the program is read out from the storage portion and is executed the process shown in the flowchart of FIG. 3. Since the process content has already been discussed, redundant discussion is eliminated.

It should be noted that the storage medium 22 may be built-in the difference judgment processing portion 2.

As set forth above, with the present invention, upon performing encoding of the image by determining the motion vector amount of the image, judgment is made whether the difference of respective motion vector amounts of adjacent macro blocks falls within the range of the preliminarily set difference threshold value and the motion vector amount of the macro block currently on process is made the same as the motion vector amount of one preceding macro block when the difference of respective motion vector amounts of adjacent macro blocks falls within the range of the difference threshold value. Thus, assignment of the coding amount for the portion where the most significant variation is caused, can be made large to realize improvement of the image quality with reducing the generated code amount.

Although the present invention has been illustrated and described with respect to exemplary embodiment thereof, it should be understood by those skilled in the art that the foregoing and various other changes, omission and additions may be made therein and thereto, without departing from the spirit and scope of the present invention. Therefore, the present invention should not be understood as limited to the specific embodiment set out above but to include all possible embodiments which can be embodied within a scope encompassed and equivalent thereof with respect to the feature set out in the appended claims.

What is claimed is:

1. An image encoding device for performing image encoding by determining a motion vector amount of an image comprising:
judgment processing means for processing judgment whether a motion vector amount calculated by using a preliminarily set difference threshold value can be replaced with a motion vector amount one preceding macro block.

2. An image encoding device as set forth in claim 1, wherein said judgment processing means comprises means for making judgment whether a difference of motion vector amounts of adjacent macro blocks falls within a range of said difference threshold value upon determination of said motion vector amount, and means for making the motion vector amount of the macro block currently on process the same as the motion vector amount of one preceding macro block when judgment is made that the difference of motion vector amounts of adjacent macro blocks falls within the range of said difference threshold value.

3. An image encoding device as set forth in claim 2, wherein said motion vector data of the macro block currently on process is converted into “1” of bit amount 1 by making the motion vector amount of the macro block currently on process the same as the motion vector amount of one preceding macro block.

4. An image encoding device as set forth in claim 2, wherein when the difference of the motion vector amounts of adjacent macro blocks falls within the range of said difference threshold value, the motion vector data of the right-hand adjacent macro block on a screen is converted into the motion vector data into “1”.

5. An image encoding device as set forth in claim 1, wherein when the difference of the motion vector amounts of adjacent macro blocks falls within the range of said difference threshold value, the motion vector block of the macro block to be finally processed is replaced with the motion vector amount of the macro block processed at first.

6. An image encoding method for performing encoding of an image for determining a motion vector amount of said image comprising a step of:
processing judgment whether a motion vector amount calculated by using a preliminarily set difference threshold value can be replaced with a motion vector amount one preceding macro block.

7. An image encoding method as set forth in claim 6, wherein said judgment processing step comprises:
step of making judgment whether a difference of motion vector amounts of adjacent macro blocks falls within a range of said difference threshold value upon determination of said motion vector amount, and
step of making the motion vector amount of the macro block currently on process the same as the motion vector amount of one preceding macro block when judgment is made that the difference of motion vector amounts of adjacent macro blocks falls within the range of said difference threshold value.

8. An image encoding method as set forth in claim 7, wherein said motion vector data of the macro block currently on process is converted into “1” of bit amount 1 by making the motion vector amount of the macro block currently on process the same as the motion vector amount of one preceding macro block.

9. An image encoding method as set forth in claim 7, wherein when the difference of the motion vector amounts of adjacent macro blocks falls within the range of said difference threshold value, the motion vector data of the right-hand adjacent macro block on a screen is converted into the motion vector data into “1”.

10. An image encoding method as set forth in claim 6, wherein when the difference of the motion vector amounts of adjacent macro blocks falls within the range of said difference threshold value, the motion vector block of the macro block to be finally processed is replaced with the motion vector amount of the macro block processed at first.

11. A storage medium storing a program for making a computer to execute an image encoding process for encoding of an image for determining a motion vector amount of said image comprising a step of:
processing judgment whether a motion vector amount calculated by using a preliminarily set difference threshold value can be replaced with a motion vector amount one preceding macro block.

12. A storage medium as set forth in claim 11, wherein said judgment processing step comprises:
step of making judgment whether a difference of motion vector amounts of adjacent macro blocks falls within a range of said difference threshold value upon determination of said motion vector amount, and
step of making the motion vector amount of the macro block currently on process the same as the motion vector amount of one preceding macro block when judgment is made that the difference of motion vector amounts of adjacent macro blocks falls within the range of said difference threshold value.

13. A storage medium as set forth in claim 12, wherein said motion vector data of the macro block currently on process is converted into “1” of bit amount 1 by making the motion vector amount of the macro block currently on process the same as the motion vector amount of one preceding macro block.

14. A storage medium as set forth in claim 12, wherein when the difference of the motion vector amounts of adjacent macro blocks falls within the range of said difference threshold value, the motion vector data of the right-hand adjacent macro block on a screen is converted into the motion vector data into “1”.

15. A storage medium as set forth in claim 11, wherein when the difference of the motion vector amounts of adjacent macro blocks falls within the range of said difference threshold value, the motion vector block of the macro block to be finally processed is replaced with the motion vector amount of the macro block processed at first.
